(19) United States
(12) Patent Application Publication
(10) Pub. No.: US 2025/0214901 A1
(43) Pub. Date: Jul. 3, 2025

(54) COMPOSITE MATERIAL, FILM, AND PHOTOELECTRIC DEVICE

(71) Applicants: Guangdong Juhua Research Institute of Advanced Display, Guangzhou (CN); TCL Technology Group Corporation, Huizhou (CN)

(72) Inventor: Hua JIANG, Guangzhou (CN)

(73) Assignees: Guangdong Juhua Research Institute of Advanced Display, Guangzhou (CN); TCL Technology Group Corporation, Huizhou (CN)

(21) Appl. No.: 18/990,994

(22) Filed: Dec. 20, 2024

(30) Foreign Application Priority Data
Dec. 30, 2023 (CN) 202311873607.6

(51) Int. Cl. C04B 35/453; B82Y 20/00; C09K 11/88; H10K 50/115; H10K 50/15; H10K 85/10

(52) U.S. Cl. CPC C04B 35/453; C09K 11/883; H10K 85/1135; H10K 85/141; H10K 85/151; B82Y 20/00; C04B 2235/3284; C04B 2235/444; H10K 50/115; H10K 50/156

(57) ABSTRACT

Disclosed are a composite material, a film, and a photoelectric device. The composite material includes a first metal oxide and a metal halide. The metal halide includes magnesium element. A conductivity of the first metal oxide is adjustable by adding the metal halide, thereby meeting needs of different application scenarios.

This application claims priority to Chinese Application No. 202311873607.6, entitled “COMPOSITE MATERIAL AND PHOTOELECTRIC DEVICE COMPRISING COMPOSITE MATERIAL”, filed on Dec. 30, 2023. The entire disclosures of the above application are incorporated herein by reference.

### TECHNICAL FIELD

The present disclosure relates to a field of photoelectric materials, and in particular to a composite material, a film, and a photoelectric device.

### BACKGROUND

A metal oxide refers to a compound formed by a combination of metal element and oxygen element. According to a conductivity type, the metal oxide is classified as a conductor, a semiconductor or an insulator. A semiconductor metal oxide is a N-type metal oxide or a P-type metal oxide. The metal oxide is widely used in a light-emitting device, a photovoltaic cell, a supercapacitor, a photodetector and other photoelectric devices because of good conductivity, and the metal oxide might be configured as a carrier functional material or an electrode material.

Different application scenarios have different requirements for the conductivity of the metal oxide. Therefore, how to realize an adjustable conductivity of the metal oxide is a technical problem to be solved in the present disclosure.

### Technical Solution

In view of this, the present disclosure provides a composite material, a film, and a photoelectric device.

According to a first aspect, the present disclosure provides a composite material including a first metal oxide and a metal halide. The metal halide includes magnesium element.

According to a second aspect, the present disclosure further provides a film including a first metal oxide and a metal halide. The metal halide includes magnesium element.

According to a third aspect, the present disclosure further provides a photoelectric device including an anode, a cathode, and multiple functional layers disposed between the anode and the cathode. At least one of the multiple functional layers includes a metal halide and a first metal oxide including magnesium element.

According to the photoelectric device provided by the present disclosure, a device efficiency of the photoelectric device might be improved by regulating the conductivity of at least one functional layer.

has a high luminous efficiency.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings might be obtained based on these drawings.

FIG. 1 is a schematic diagram of a first photoelectric device provided by an embodiment of the present disclosure.

FIG. 2 is a schematic diagram of a second photoelectric device provided by another embodiment of the present disclosure.

### DETAILED DESCRIPTION

Technical solutions in embodiments of the present disclosure will be clearly and completely described below in conjunction with drawings in the embodiments of the present disclosure. Obviously, the embodiments are only a part of embodiments of the present disclosure, rather than all the embodiments. Based on the embodiments in the present disclosure, all other embodiments obtained by those skilled in the art without creative work fall within the protection scope of the present disclosure.

Unless otherwise defined, all professional and scientific terms used herein have same meanings as those familiar to those skilled in the art. Furthermore, any method or any material similar or equivalent to that described might be used in the present disclosure. A preferred embodiment and a preferred material described herein are for illustrative purposes only, but are not intended to limit contents of the present disclosure.

An order of description of the following embodiments is not intended to limit a preferred order of the embodiments.

Each embodiment of the present disclosure may be presented in a form of range. It should be understood that a description in the form of range is merely for convenience and brevity, and should not be construed as a limitation on the scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In the present disclosure, the term “including” means “including but not limited to”.

In the present disclosure, the term “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c. Each of a, b, and c may be single or plural.

In the present disclosure, the term “and/or” is used to describe an association of associated objects. For example, “A and/or B” may refer to three cases: a first case refers to the presence of A alone, a second case refers to the presence of both A and B, and a third case refers to the presence of B alone, where A and B each may be singular or plural.

In the present disclosure, a description of “the A layer is formed on a side of the B layer” or “the A layer is formed on a side of the B layer away from the C layer” may mean that the A layer is directly formed on the side of the B layer or the side of the B layer away from the C layer, that is, the A layer is in contact with the B layer. It may also mean that the A layer is indirectly formed on the side of the B layer or the side of the B layer away from the C layer, that is, another film layer may be formed between the A layer and the B layer.

In the present disclosure, the term “particle size” refers to a diameter of a nanoparticle.

In a first aspect, an embodiment of the present disclosure provides a composite material. The composite material includes a first metal oxide and a metal halide. The metal halide includes magnesium element. A conductivity of the first metal oxide is adjustable by adding the metal halide, thereby meeting needs of different application scenarios.

In the composite material, the first metal oxide may be nanoparticle-shaped, nanosheet-shaped, nanoneedle-shaped or nanorod-shaped.

In some embodiments, the first metal oxide is in the form of nanoparticles, and an average particle size of the first metal oxide ranges from 2 nm to 20 nm, such as 2 nm, 5 nm, 8 nm, 10 nm, 12 nm, 15 nm, 20 nm, or a value between any two thereof.

In some embodiments, the first metal oxide includes one or more of ZnO and Zn₍₁₋ₓ₎MgₓO, where x is greater than 0 and not more than 0.5.

In some embodiments, x is not less than 0.05 and not more than 0.2, such as 0.05, 0.1, 0.15, 0.2, or a value between any two thereof.

To regulate a conductivity of Zn₍₁₋ₓ₎MgₓO, in some embodiments, the first metal oxide is Zn₍₁₋ₓ₎MgₓO, and the metal halide is MgCl₂.

In order to regulate the conductivity of the composite material conveniently, in some embodiments, a mass ratio of the first metal oxide to the metal halide is 1:(0.01˜0.1), such as 1:0.01, 1:0.03, 1:0.05, 1:0.08, 1:0.1, or a value between any two thereof.

To appropriately reduce the conductivity of Zn₍₁₋ₓ₎MgₓO, in some embodiments, the first metal oxide is Zn₍₁₋ₓ₎MgₓO, where x is not less than 0.05 and not more than 0.2, and the metal halide is MgCl₂. A mass ratio of Zn₍₁₋ₓ₎MgₓO to MgCl₂ is 1:(0.01˜0.1).

The composite material may be in the form of a solid state, a solution, or a dispersion liquid. When the composite material is in the form of the solution or the dispersion liquid, a solvent of the solution or a dispersion medium of the dispersion liquid may include but not limited to one or more of an alkane, an aromatic hydrocarbon, a halogenated alkane, an alcohol compound, an ether compound, a furan compound, a pyridine compound, an amide compound, and a sulfone compound.

The alkane may include but not limited to one or more of nonane, decane, dodecane, terpene, butylcyclohexane, N-octane, N-hexane, N-heptane, N-nonane, N-decane, cyclohexane, and cyclopentane. The aromatic hydrocarbons may include but not limited to one or more of diethylbenzene, trimethylbenzene, n-propylbenzene, cumene, p-cymene, butylbenzene, 1-methylnaphthalene and indene. The halogenated alkane may include but not limited to one or more of dichloromethane, trichloromethane, and carbon tetrachloride. The alcohol compound may include but not limited to one or more of methanol, ethanol, 1-propanol, 1-butanol, ethylene glycol, and glycerin. The ether compound may include but not limited to 2-methoxyethanol. The furan compound may include but not limited to tetrahydrofuran. The pyridine compound may include but not limited to pyridine. The amide compound may include but not limited to N,N-dimethylformamide. The sulfone compound may include but not limited to dimethyl sulfoxide. In one embodiment, the solvent of the solution or the dispersion medium of the dispersion liquid is ethanol.

In a second aspect, an embodiment of the present disclosure provides a method for preparing a composite material. The method for preparing a composite material may be used for preparing any one of the composite material as described above. The method includes a step that the first metal oxide and the metal halide are mixed to obtain the composite material. Both the first metal oxide and the metal halide are as previously described.

In some embodiments, in the step of mixing the first metal oxide and the metal halide, a mass ratio of the first metal oxide to the metal halide is 1:(0.01˜0.1), such as 1:0.01, 1:0.03, 1:0.05, 1:0.08, 1:0.1, or a value between any two thereof.

In some embodiments, the step of mixing the first metal oxide and the metal halide includes: providing a first dispersion liquid including the first metal oxide, dispersing or dissolving the metal halide in the first dispersion liquid to obtain the composite material. A dispersion medium of the first dispersion liquid may include but not limited to one or more of the alkane, the aromatic hydrocarbon, the halogenated alkane, the alcohol compound, the ether compound, the furan compound, the pyridine compound, the amide compound, and the sulfone compound. A concentration of the first metal oxide in the first dispersion liquid ranges from 5 mg/mL to 50 mg/mL.

In some embodiments, the step of mixing the first metal oxide and the metal halide includes: providing a second dispersion liquid including the metal halide, dispersing or dissolving the first metal oxide in the second dispersion liquid to obtain the composite material. A dispersion medium of the second dispersion liquid may include but not limited to one or more of the alkane, the aromatic hydrocarbon, the halogenated alkane, the alcohol compound, the ether compound, the furan compound, the pyridine compound, the amide compound, and the sulfone compound. A concentration of the metal halide in the second dispersion liquid ranges from 0.05 mg/mL to 5 mg/mL.

In a third aspect, an embodiment of the present disclosure provides a film. A material of the film includes the first metal oxide and the metal halide. In one embodiment, the material of the film is formed of the first metal oxide and the metal halide. A conductivity of the film is regulated by adding the metal halide. Both the first metal oxide and the metal halide are as previously described.

In order to regulate the conductivity of the film conveniently, in some embodiments, in the film, a mass ratio of the first metal oxide to the metal halide is 1:(0.01˜0.1), such as 1:0.01, 1:0.03, 1:0.05, 1:0.08, 1:0.1, or a value between any two thereof.

In some embodiments, a thickness of the film ranges from 10 nm to 100 nm, such as 10 nm, 30 nm, 50 nm, 80 nm, 100 nm, or a value between any two thereof.

In a fourth aspect, an embodiment of the present disclosure provides a method for preparing a film including step S1 and step S2. The method for preparing a film may be used for preparing any one of the film as described above.

In the step S1, a third dispersion liquid including the first metal oxide and the metal halide is deposited, or a solution including the first metal oxide and the metal halide is deposited.

Furthermore, in the step S1, a deposition method of the third dispersion liquid or the solution is a solution method, and the solution method includes but not limited to one or more of a spin coating method, a printing method, an ink jet printing method, a blade coating method, a dipping and pulling method, a soaking method, a spray coating method, a roll coating method, a casting method, a slit coating method, and a strip coating method. A method for preparing the third dispersion or the solution refers to the previous description with respect to the composite material.

In the step S2, the third dispersion liquid deposited or the solution deposited is subjected to a drying treatment to obtain the film.

In the step S2, The dry treatment includes but not limited to one or more of heating and vacuum drying.

In order to regulate the conductivity of the film conveniently, in some embodiments, in the third dispersion liquid, a mass ratio of the first metal oxide to the metal halide is 1:(0.01˜0.1), such as 1:0.01, 1:0.03, 1:0.05, 1:0.08, 1:0.1, or a value between any two thereof.

In a fifth aspect, an embodiment of the present disclosure provides a photoelectric device. The photoelectric device includes but not limited to a light-emitting device, a solar cell or a photodetector. The photoelectric device includes an anode and a cathode disposed oppositely, and multiple functional layers disposed between the anode and the cathode. At least one of the multiple functional layers includes the composite material as described above, or the composite material prepared by the method for preparing a composite material as described above, or at least one of the multiple functional layers includes the film as described above, or the film prepared by the method for preparing a film, thereby improving the photoelectric performance and performance stability of the photoelectric device.

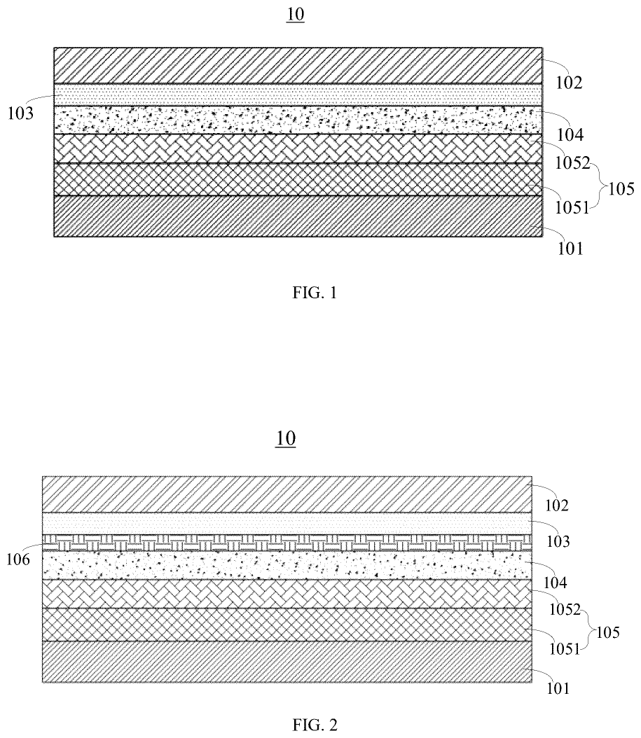

In some embodiments, referring to FIG. 1 and FIG. 2, the photoelectric device 10 includes the anode 101 and the cathode 102 disposed oppositely, and multiple functional layers disposed between the anode 101 and the cathode 102. The multiple functional layers include an electron functional layer 103. A material of the electron functional layer 103 includes the composite material as described above, or the composite material prepared by the method for preparing a composite material as described above, or the electron functional layer 103 includes the film as described above, or the film prepared by the method for preparing a film. A device efficiency of the photoelectric device 10 might be improved by regulating the conductivity of the electron functional layer 103, thereby improving the photoelectric performance and performance stability of the photoelectric device.

A thickness of the electron functional layer 103 may range from 10 nm to 100 nm. The electron functional layer 103 may have a single-layer structure or a multi-layers structure, for example, the electron functional layer 103 includes one or more of an electron injection layer, an electron transport layer, and a hole blocking layer.

In one embodiment, the electron functional layer 103 includes the electron injection layer, the electron transport layer, and the hole blocking layer disposed sequentially in stack. The electron transport layer is disposed between the electron injection layer and the hole blocking layer, and the electron injection layer is closer to the cathode 102 than the hole blocking layer.

In another embodiment, the electron functional layer 103 includes the electron transport layer and the hole blocking layer disposed in stack. The electron transport layer is closer to the cathode 102 than the hole blocking layer.

In another embodiment, the electron functional layer 103 includes the electron injection layer and the electron transport layer disposed in stack. The electron injection layer is closer to the cathode 102 than the electron transport layer.

Under a condition that the electron functional layer 103 has the multi-layers structure, one or more layers of the electron functional layer 103 include the composite material as described above, or the composite material prepared by the method for preparing a composite material as described above, or the film as described above, or the film prepared by the method for preparing a film.

In some embodiments, the photoelectric device 10 is a light-emitting device, referring to FIG. 1 and FIG. 2, the photoelectric device 10 further includes a light-emitting layer 104 disposed between the electron functional layer 103 and the anode 101. A material of the light-emitting layer 104 includes an organic light-emitting material and a quantum dot light-emitting material.

The organic light-emitting material may include but not limited to one or more of 4,4′-bis(N-carbazole)-1,1′-biphenyl: tris[2-(p-tolyl) pyridinyl iridium (III)](CBP:Ir(mppy)₃), 4,4,4″-tris(carbazol-9-yl)triphenylamine: tris[2-(p-tolyl)pyridinyl iridium](TCTX:Ir(mmpy)), diarylanthracene derivatives, stilbene aromatic derivatives, pyrene derivatives, fluorene derivatives, a TBPe fluorescent material, a TTPX fluorescent material, a TBRb fluorescent material, a DBP fluorescent material, a DBP fluorescent material, a DBP fluorescent material, a delayed fluorescence material, a TTA material, a thermally activated delayed fluorescence material, a polymer including a B-N covalent, a hybrid local charge transfer excited state material, an exciplex luminescent material, polyacetylene and derivatives thereof, polythiophene and derivatives thereof, and polyfluorene and derivatives thereof.

The quantum dot light-emitting material may include but not limited to one or more of a red quantum dot, a green quantum dot, and a blue quantum dot. The quantum dot light-emitting material may include but not limited to one or more of a quantum dot with a single component, a quantum dot with a core-shell structure, an inorganic perovskite quantum dot, an organic perovskite quantum dot, and an organic-inorganic hybrid perovskite quantum dot. The quantum dot with a core-shell structure includes one or more shell layers. An average particle size of the quantum dot light-emitting material may range from 2 nm to 20 nm, such as 2 nm, 5 nm, 8 nm, 10 nm, 13 nm, 15 nm, 20 nm, or a value between any two thereof.

For the quantum dot with a single component and the quantum dot with a core-shell structure, a material of the quantum dot with a single component, a material of the core of the quantum dot with a core-shell structure, and a material of a shell layer of the quantum dot with a core-shell structure each include one or more of a group II-VI compound, a group IV-VI compound, a group III-V compound, a group III-VI compound, and a group I-III-VI compound.

The group II-VI compound may include but not limited to one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound may include but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-VI compound may include but not limited to one or more of In₂S₃, In₂Se₃, InGaS₃, and InGaSe₃. The group III-V compound may include but not limited to one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The group I-III-VI compound may include but not limited to one or more of AgInS, AgInS₂, CuInS, CuInS₂, AgGaS₂, CuGaS₂, CuGaO₂, AgGaO₂, AgAlO₂, AgInGaS₂, and CuInGaS₂.

The inorganic perovskite quantum dot has a general structural formula of AMX₃. A is Cs⁺, M is a divalent metal cation including but not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but not limited to Cl⁻, Br⁻, or I⁻.

The organic perovskite quantum dot has a general structural formula of CMX₃. C is a formamidyl, M is a divalent metal cation including but not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but not limited to Cl⁻, Br⁻, or I⁻.

The organic-inorganic hybrid perovskite quantum dot has a general structural formula of BMX₃. B is an organic amine cation including but not limited to CH₃(CH₂)ₙ₋₂NH³⁺ or NH₃(CH₂)ₙNH₃²⁺, n is not less than 2, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion selected from one or more of Cl⁻, Br⁻, or I⁻.

In some embodiments, when the material of the light-emitting layer 104 includes the quantum dot light-emitting material, the quantum dot light-emitting material is attached with a ligand, thereby improving a solution processing performance of the quantum dot light-emitting material, and further improving a light-emitting efficiency of the photoelectric device 10. The ligand may be a ligand known in the art, including but not limited to one or more of a C1˜C30 aliphatic carboxylic acid ligand, a C6˜C30 aromatic carboxylic acid ligand, a C1˜C30 aliphatic thiol ligand, a C6˜C30 aromatic thiol ligand, a C1˜C30 aliphatic amine ligand, a C6˜C30 aromatic amine ligand, a C1˜C30 aliphatic phosphine ligand, a C6˜C30 aromatic phosphine ligand, a C6˜C30 aromatic phosphate ester ligand, and a halogen ligand.

The C1˜C30 aliphatic carboxylic acid ligand includes but not limited to one or more of octanoic acid, nonanoic acid, decanoic acid, undecanoic acid, dodecanoic acid, tetradecanoic acid, hexadecanoic acid, octadecanoic acid, eicosanoic acid, tetracosanoic acid, hexacosanoic acid, oleic acid, linoleic acid, arachidic acid, arachidonic acid, erucic acid and docosahexaenoic acid. The C6˜C30 aromatic carboxylic acid ligand includes but not limited to one or more of benzoic acid, bibenzoic acid, and 1-naphthoic acid. The C1˜C30 aliphatic thiol ligand includes but not limited to one or more of hexanethiol, octanethiol, nonanethiol, decanethiol, undecanethiol, dodecanethiol, hexadecanethiol, and octadecanethiol. The C6˜C30 aromatic thiol ligand includes but not limited to one or more of thiophenol, triphenylmethyl mercaptan, and p-terphenyl-4,4″-dithiol. The C1˜C30 aliphatic amine ligand includes but not limited to one or more of hexylamine, octylamine, dioctylamine, trioctylamine, nonylamine, decylamine, dodecylamine, tridecylamine, tetradecylamine, pentadecylamine, hexadecylamine, heptadecylamine, octadecylamine, and oleylamine. The C6˜C30 aromatic amine ligand includes but not limited to one or more of aniline, aprindine, 4-octylaniline, and benzidine. The aliphatic phosphine ligand includes but not limited to one or more of trimethylphosphine, triethylphosphine, tripropylphosphine, tributylphosphine, trihexylphosphine, trioctylphosphine, tridecylphosphine, tributylphosphine oxide, trihexylphosphine oxide, trioctylphosphine oxide, and tridecylphosphine oxide. The C6˜C30 aromatic phosphine ligand includes but not limited to one or more of bis[2-(diphenylphosphino)ethyl]phenylphosphine and triphenylphosphine oxide. The C6˜C30 aromatic phosphate ester ligand includes but not limited to one or more of p-xylylenediphosphonic acid tetraethyl ester and diphenylphosphinic acid ethyl ester. The halogen ligand includes but not limited to one or more of —Cl, —F, —I, and —Br.

In some embodiments, the photoelectric device 10 further includes a hole functional layer 105 disposed between the electron functional layer 103 and the anode 101. Referring to FIG. 1 and FIG. 2, the photoelectric device 10 is the light-emitting device, and the hole functional layer 105 is disposed between the anode 101 and the light-emitting layer 104.

A thickness of the hole functional layer 105 may range from 10 nm to 100 nm. The hole functional layer 105 may have a single-layer structure or a multi-layers structure, for example, the hole functional layer 105 includes one or more of a hole injection layer, a hole transport layer, and an electron blocking layer.

In one embodiment, the hole functional layer 105 includes the hole injection layer, the hole transport layer, and the electron blocking layer disposed sequentially in stack. The hole transport layer is disposed between the hole injection layer and the electron blocking layer, and the hole injection layer is closer to the anode 101 than the electron blocking layer.

In another embodiment, the hole functional layer 105 includes the hole transport layer and the electron blocking layer disposed in stack. The hole transport layer is closer to the anode 101 than the electron blocking layer.

In another embodiment, the hole functional layer 105 includes the hole injection layer and the hole transport layer disposed in stack. The hole injection layer is closer to the anode 101 than the hole transport layer.

A material of the hole functional layer 105 includes but not limited to one or more of an organic compound, a first inorganic compound material, and a second inorganic compound material. The organic compound includes but not limited to one or more of poly(3,4-ethylenedioxythiophene)-poly(styrenesulfonate) (PEDOT:PSS, CAS: 155090-83-8), copper(II) phthalocyanine (CAS: 147-14-8), titanyl phthalocyanine (CAS: 26201-32-1), 2,3,5,6-tetrafluoro-7,7,8,8-tetracyanoquinodimethane (CAS: 29261-33-4), hexaazatriphenylenehexacabonitrile (CAS: 105598-27-4), polyaniline (CAS: 25233-30-1), polypyrrole (CAS: 30604-81-0), poly(3-hexylthiophene-2,5-diyl)(CAS: 104934-50-1), poly(n-vinylcarbazole)(PVK, CAS: 25067-59-8), 4,4′-Bis(N-carbazolyl)-1,1′-biphenyl (CBP, CAS: 58328-31-7), poly[N,N′-bis(4-butylphenyl)-N,N′-bis(phenyl)-benzi (CAS: 472960-35-3), 4,4′-cyclohexylidenebis[N,N-bis(4-methylphenyl)aniline](TAPC, CAS: 58473-78-2), poly(9,9-dioctylfluorene-co-N-(4-butylphenyl)diphenylamine) (TFB, CAS: 220797-16-0), poly[(9,9-dioctylfluorenyl-2,7-diyl)-alt-(4,4′-(N-(4-butylphenyl) (CAS: 223569-31-1), 4,4′,4″-tris(N-3-methylphenyl-N-phenylamino)triphenylamine (CAS: 124729-98-2), 4,4′,4″-tris(carbazol-9-yl)-triphenylamine(TCTA, CAS: 139092-78-7), 4,4′,4″-tris[2-naphthyl(phenyl)amino]triphenylamine (CAS: 185690-41-9), N,N′-bis-(1-naphthalenyl)-N,N′-bis-phenyl-(1,1′-biphenyl)-4,4′-diamine (NPB, CAS: 123847-85-8), N,N′-bis(3-methylphenyl)-N,N′-diphenyl-benzidine (TPD, CAS: 65181-78-4), N,N′-bis[4-(diphenylamino)phenyl]-N,N′-diphenylbenzidine (CAS: 209980-53-0), N2,N7-diphenyl-N2,N7-di-m-tolyl-9,9′-spirobi[fluorene]-2,7-diamine (Spiro-TPD, CAS: 1033035-83-4), N2,N7-di-1-naphthalenyl-N2,N7-diphenyl-9,9′-spirobi[9h-fluorene]-2,7-diamine (CAS: 932739-76-9), poly[bis(4-phenyl)(2,4,6-trimethylphenyl)amine](PTTA, CAS: 1333317-99-9), poly((9,9-dioctylfluorenyl-2,7-diyl)-alt-(9-(2-ethylhexyl)-carbazole-3,6-diyl)) (PF8Cz), and 2,2′,7,7′-Tetrakis[N,N-di(4-methoxyphenyl)amino]-9,9′-spirobifluorene (Spiro-omeTAD, CAS: 207739-72-8).

The first inorganic compound material includes but not limited to one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide.

The second inorganic compound material includes but not limited to one or more of doped-type second inorganic compounds. A host material of a doped-type second inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, or tungsten sulphide, and a doping element of the doped-type second inorganic compound is selected from one or more of nickel, molybdenum, tungsten, vanadium, chromium, copper and platinum group metal elements. A percentage of a molar amount of the doping element to a total molar amount of the doped second inorganic compound is not more than 50%.

Under a condition that the hole functional layer 105 includes multiple materials and the hole functional layer 105 has the multi-layers structure, the multiple materials may all be in the same layer, or may be in different layers, or may be partially in the same layer.

In one embodiment, referring to FIG. 1 and FIG. 2, the hole functional layer 105 is formed of the hole injection layer and the hole transport layer disposed in stack. The material of the hole functional layer 105 includes PEDOT:PSS and TFB, a material of the hole injection layer is PEDOT:PSS, and a material of the hole transport layer is TFB.

In another embodiment, the material of the hole functional layer 105 includes PEDOT:PSS and PF8Cz, a material of the hole injection layer is PEDOT:PSS, and a material of the hole transport layer is PF8Cz. As PF8Cz has stronger structural rigidity than TFB, it might effectively suppress a problem of electron leakage in the photoelectric device 10, thereby further improving the device efficiency of the photoelectric device 10.

It should be noted that some photoelectric devices have a problem of electron-hole transport imbalance, resulting in poor device efficiencies. For example, a quantum dot light emitting diode (QLED) has a problem that an electron injection level is much greater than a hole injection level, especially a blue quantum dot light emitting diode. In order to promote an electron-hole transport equilibrium, on the one hand, the electron injection level may be appropriately decreased, and on the other hand, the hole injection level may be increased.

In the photoelectric device 10 of the embodiments, the electron functional layer 103 may include the composite material as described above, or the composite material prepared by the method for preparing a composite material as described above, or the electron functional layer 103 may include the film as described above, or the film prepared by the method for preparing a film. The electron injection level is decreased by appropriately reducing the conductivity of the electron functional layer 103, thereby promoting electron-hole transport balance, and further improving the device efficiency of the photoelectric device 10.

In some embodiments, referring to FIG. 2, the multiple functional layers further include an auxiliary layer disposed between the electron functional layer 103 and the light-emitting layer 104, thereby further reducing the electron injection level of the photoelectric device 10, and further promoting electron-hole transport balance. A material of the auxiliary layer 106 includes a polymer material. The polymer material may be selected from one or more of polymethyl methacrylate, polyethylene glycol terephthalate, polyvinyl pyrrolidone, polyethylene oxide, and polyimide.

In order to further promote electron-hole transport balance of the photoelectric device 10, in some embodiments, an average thickness of the auxiliary layer 106 ranges from 1 nm to 5 nm, such as 1 nm, 2 nm, 3 nm, 4 nm, 5 nm, or a value between any two thereof.

In some embodiments, referring to FIG. 1, the multiple functional layers are formed of the anode 101, the hole functional layer 105, the light-emitting layer 104, the electron functional layer 103, and the cathode 102.

In other embodiments, referring to FIG. 1, the multiple functional layers are formed of the anode 101, the hole functional layer 105, the light-emitting layer 104, the auxiliary layer 106, the electron functional layer 103, and the cathode 102.

It is understood that the photoelectric device 10 may further include a substrate disposed on a side of a bottom electrode away from the multiple functional layers. The substrate may be a rigid substrate or a flexible substrate. A material of the rigid substrate includes but not limited to one or more of glass, ceramic, and silicon wafer, and a material of the flexible substrate includes but not limited to one or more of polyimide, polycarbonate, polymethyl methacrylate, polyethylene glycol terephthalate, polyethylene naphthalene-2,6-dicarboxylate, and polyethersulfone.

A method for preparing each functional layer in the photoelectric device includes but not limited to a chemical method and/or a physical method. The chemical method includes but not limited to one or more of a chemical vapor deposition method, a continuous ion layer adsorption and reaction method, an anodic oxidation method, an electrolytic deposition method, and a co-precipitation method. The physical method includes but not limited to a physical coating method and a solution method. The physical coating method includes but not limited to one or more of a thermal evaporation coating method, an electron beam evaporation coating method, a magnetron sputtering method, a multi-arc ion coating method, a physical vapor deposition method, an atomic layer deposition method, and a pulsed laser deposition method. The solution method includes but not limited to one or more of a spin coating method, a printing method, an ink jet printing method, a blade coating method, a dipping and pulling method, a soaking method, a spray coating method, a roll coating method, a casting method, a slit coating method, and a strip coating method.

After all functional layers of the photoelectric device having been prepared, an encapsulating step is performed. The encapsulating step may be a commonly used machine encapsulating or a manually encapsulating. In the encapsulating environment, a content of oxygen and a content of water are both lower than 0.1 ppm to ensure a stability of the photoelectric device. Specifically, an encapsulating material used for forming an encapsulation layer may be selected from one or more of an ultraviolet adhesive, a metal film, and a glass adhesive. In one embodiment, the encapsulating material is an acrylic resin or an epoxy resin.

An embodiment of the present disclosure provides an electronic apparatus including the photoelectric device according to any one of the embodiments of the present disclosure. The electronic device may be any electronic product with a display function, including but not limited to a smartphone, a tablet personal computer, a notebook computer, a video telephone, an electronic book reader, a laptop personal computer, a netbook computer, a workstation, a server, a personal digital assistant, a portable multimedia player, a mobile medical machine, a camera, a game console, a car navigation, an electronic billboard, a smart wearable device, or a virtual reality device. The smart wearable device may be, for example, a smart bracelet, a smart watch, or the like.

In the following, the present disclosure is specifically described by specific embodiments, and the following examples are only partial examples of the present disclosure and are not limited to the present disclosure.

### Material Example 1

This embodiment provides a composite material and preparation method thereof. The composite material includes Zn_{0.85}Mg_{0.15}O nanoparticles and MgCl₂. In the composite material, a mass ratio of Zn_{0.85}Mg_{0.15}O to MgCl₂ is 1:0.02. The preparation method includes steps S1.1 and S1.2.

In step S1.1, 6 mg of MgCl₂ was dissolved in 10 mL of a Zn_{0.85}Mg_{0.15}O solution to obtain a solution including the composite material. In the Zn_{0.85}Mg_{0.15}O solution, a concentration of Zn_{0.85}Mg_{0.15}O was 30 mg/mL, and a solvent of the Zn_{0.85}Mg_{0.15}O solution was ethanol.

In step S1.2, the solution including the composite material was spin-coated on one side of the substrate under a nitrogen atmosphere with a normal temperature and a normal pressure.

The solution including the composite material was spin-coated on one side of the substrate under a nitrogen atmosphere with a normal temperature and a normal pressure, and then a film including the composite material was formed after heating at 100° C. under a nitrogen atmosphere for curing. An average thickness of the film was 35 nm.

A method for preparing the Zn_{0.85}Mg_{0.15}O solution includes steps S10-S30.

In step S10, 5.5 g of zinc acetate dihydrate, 0.46 g of magnesium acetate tetrahydrate and 150 mL of ethanol were mixed and stirred at 80° C. to completely dissolve zinc acetate dihydrate to obtain a mixture.

In step S20, the mixture was placed in a water bath at 0° C., and 20 mL of a potassium hydroxide aqueous solution was slowly added to the mixture and stirred until it was clear to obtain a homogeneous and transparent solution. In the potassium hydroxide aqueous solution, a concentration of potassium hydroxide was 1.75 mol/L.

In step S30, heptane was added to the solution prepared in step S20 to generate a precipitate, where a volume ratio of the solution to heptane is 3:1, then the precipitate was collected after centrifuging. The precipitate was dissolved in methanol, then adding heptane, centrifuging and collecting a precipitate were performed sequentially, repeating twice, a precipitate finally collected was Zn_{0.85}Mg_{0.15}O nanoparticles. The Zn_{0.85}Mg_{0.15}O nanoparticles were dissolved in ethanol to obtain the Zn_{0.85}Mg_{0.15}O solution.

### Material Example 2

This embodiment provides a composite material and preparation method thereof. The composite material includes Zn_{0.85}Mg_{0.15}O nanoparticles and MgCl₂. In the composite material, a mass ratio of Zn_{0.85}Mg_{0.15}O to MgCl₂ is 1:0.01.

Compared with the method for preparing the composite material in Material Example 1, a method for preparing the composite material in this Example has a difference that “6 mg of MgCl₂” in step S1.1 is replaced with “3 mg of MgCl₂”.

### Material Example 3

This embodiment provides a composite material and preparation method thereof. The composite material includes Zn_{0.85}Mg_{0.15}O nanoparticles and MgCl₂. In the composite material, a mass ratio of Zn_{0.85}Mg_{0.15}O to MgCl₂ is 1:0.05.

Compared with the method for preparing the composite material in Material Example 1, a method for preparing the composite material in this Example has a difference that “6 mg of MgCl₂” in step S1.1 is replaced with “15 mg of MgCl₂”.

### Material Example 4

This embodiment provides a composite material and preparation method thereof. The composite material includes Zn_{0.85}Mg_{0.15}O nanoparticles and MgCl₂. In the composite material, a mass ratio of Zn_{0.85}Mg_{0.15}O to MgCl₂ is 1:0.1.

Compared with the method for preparing the composite material in Material Example 1, a method for preparing the composite material in this Example has a difference that “6 mg of MgCl₂” in step S1.1 is replaced with “30 mg of MgCl₂”.

### Material Example 5

This embodiment provides a composite material and preparation method thereof. The composite material includes Zn_{0.8}Mg_{0.2}O nanoparticles and MgCl₂. In the composite material, a mass ratio of Zn_{0.8}Mg_{0.2}O to MgCl₂ is 1:0.02.

Compared with the method for preparing the composite material in Material Example 1, a method for preparing the composite material in this Example has a difference that “Zn_{0.85}Mg_{0.15}O” in step S1.1 is replaced with “Zn_{0.8}Mg_{0.2}O”.

Compared with the method for preparing the Zn_{0.85}Mg_{0.15}O solution, a method for preparing a Zn_{0.8}Mg_{0.2}O solution in this Example had a difference that step S1.1 is replaced with “5.5 g of zinc acetate dihydrate, 0.62 g of magnesium acetate tetrahydrate and 150 mL of ethanol were mixed and stirred at 80° C. to completely dissolve zinc acetate dihydrate to obtain a mixture”.

### Material Comparative Example 1

This comparative example provides a composite material and preparation method thereof. The composite material includes Zn_{0.85}Mg_{0.15}O nanoparticles and KCl. In the composite material, a mass ratio of Zn_{0.85}Mg_{0.15}O to KCl is 1:0.02.

Compared with the method for preparing the composite material in Material Example 1, a method for preparing the composite material in this comparative example has a difference that “6 mg of MgCl₂” in step S1.1 is replaced with “6 mg of KCl”.

### Material Comparative Example 2

This comparative example provides a composite material and preparation method thereof. The composite material includes Zn_{0.85}Mg_{0.15}O nanoparticles and NaCl. In the composite material, a mass ratio of Zn_{0.85}Mg_{0.15}O to NaCl is 1:0.02.

Compared with the method for preparing the composite material in Material Example 1, a method for preparing the composite material in this comparative example has a difference that “6 mg of MgCl₂” in step S1.1 is replaced with “6 mg of NaCl”.

### Device Example 1

This embodiment provides a photoelectric device and a preparation method thereof. The photoelectric device is a quantum dot light emitting diode with an upright structure. Referring to FIG. 2, the photoelectric device 10 includes an anode 101, a hole functional layer 105, a light-emitting layer 104, an auxiliary layer 106, an electron functional layer 103, and a cathode 102 disposed sequentially in stack. The hole functional layer 105 is formed of a hole injection layer 1051 and a hole transport layer 1052 disposed in stack, and the hole injection layer 1051 is closer to the anode 101 than the hole transport layer 1052. The electron functional layer 103 has a single-layer structure, and the electron functional layer 103 is an electron transport layer. A light emitting area of the photoelectric device 10 is 0.04 cm².

A material of the anode 101 includes ITO, and an average thickness of the anode 101 is 50 nm. A material of the cathode 102 includes silver, and an average thickness of the cathode 102 is 100 nm. A material of the electron functional layer 103 is the composite material prepared in Material Example 1, and an average thickness of the electron functional layer 103 is 35 nm. A material of the light-emitting layer 104 is a quantum dot with a core-shell structure, where a material of the core of the quantum dot is CdZnSe, a material of a shell of the quantum dot is CdZnS, an average particle size of the quantum dot is 12 nm, an emission colour of the quantum dot is blue, and a thickness of the light-emitting layer 104 is 40 nm. A material of the hole injection layer 1051 includes PEDOT:PSS, and an average thickness of the hole injection layer 1051 is 40 nm. A material of the hole transport layer 1052 includes TFB, and an average thickness of the hole transport layer 1052 is 30 nm. A material of the auxiliary layer 106 is polymethyl methacrylate, and an average thickness of the auxiliary layer 106 is 3 nm.

A method for preparing the photoelectric device includes steps S10.1-S10.7.

In step S10.1, ITO was sputtered on one side of the substrate made of glass to obtain an ITO layer. A surface of the ITO layer was wiped with a cotton swab dipped in a small amount of soapy water to remove visible impurities on the surface. The substrate including the ITO layer was ultrasonically cleaned by deionized water for 15 minutes, acetone for 15 minutes, ethanol for 15 minutes and isopropyl alcohol for 15 minutes sequentially, and after drying, the substrate including the anode was obtained by an ultraviolet-ozone surface treatment for 20 minutes.

In step S10.2, a PEDOT:PSS aqueous solution was spin-coated on one side of the anode away from the substrate under an air atmosphere with a normal temperature and a normal pressure, and then the hole injection layer was formed by heating at 150° C. for curing.

In step S10.3, a TFB solution with a concentration of 8 mg/mL was spin-coated on the side of the hole injection layer away from the anode under a nitrogen atmosphere with a normal temperature and a normal pressure, and then the hole transport layer was formed by heating at 150° C. under a nitrogen atmosphere for curing. A solvent of the TFB solution was chlorobenzene.

In step S10.4, a quantum dot solution with a concentration of 25 mg/mL was spin-coated on one side of the hole transport layer away from the hole injection layer under a nitrogen atmosphere with a normal temperature and a normal pressure, and then the light-emitting layer was formed by heating at 80° C. under a nitrogen atmosphere for curing. A solvent of the quantum dot solution was n-hexane.

In step S10.5, a polymethyl methacrylate solution with a concentration of 0.5 mg/mL was spin-coated on one side of the light-emitting layer away from the hole transport layer under a nitrogen atmosphere with a normal temperature and a normal pressure, and then the auxiliary layer was formed by heating at 110° C. under a nitrogen atmosphere for curing.

In step S10.6, with reference to the preparation method of the composite material in Material Example 1, the electron functional layer was formed on one side of the auxiliary layer away from the light-emitting layer.

In step S10.7, a laminated structure obtained after the step S10.6 was transferred to a vacuum coating machine, evacuating to 4×10⁻⁶ mbar, then the cathode was formed on one side of the electron functional layer away from the light-emitting layer by evaporating silver through a mask plate, and finally a ultraviolet adhesive was used for encapsulation to obtain the photoelectric device.

### Device Example 2

This embodiment provides a photoelectric device and a preparation method thereof. Compared with the photoelectric device in Device Example 1, the photoelectric device in this Example has a difference that the material of the electron functional layer is replaced with the composite material prepared in Material Example 2.

Compared with the method for preparing the photoelectric device in Device Example 1, a method for preparing the photoelectric device in this Example has a difference that step S10.6 is replaced with “with reference to the preparation method of the composite material in Material Example 2, the electron functional layer was formed on one side of the auxiliary layer away from the light-emitting layer”.

### Device Example 3

This embodiment provides a photoelectric device and a preparation method thereof. Compared with the photoelectric device in Device Example 1, the photoelectric device in this Example has a difference that the material of the electron functional layer is replaced with the composite material prepared in Material Example 3.

Compared with the method for preparing the photoelectric device in Device Example 1, a method for preparing the photoelectric device in this Example has a difference that step S10.6 is replaced with “with reference to the preparation method of the composite material in Material Example 3, the electron functional layer was formed on one side of the auxiliary layer away from the light-emitting layer”.

### Device Example 4

This embodiment provides a photoelectric device and a preparation method thereof. Compared with the photoelectric device in Device Example 1, the photoelectric device in this Example has a difference that the material of the electron functional layer is replaced with the composite material prepared in Material Example 4.

Compared with the method for preparing the photoelectric device in Device Example 1, a method for preparing the photoelectric device in this Example has a difference that step S10.6 is replaced with “with reference to the preparation method of the composite material in Material Example 4, the electron functional layer was formed on one side of the auxiliary layer away from the light-emitting layer”.

### Device Example 5

This embodiment provides a photoelectric device and a preparation method thereof. Compared with the photoelectric device in Device Example 1, the photoelectric device in this Example has a difference that the material of the electron functional layer is replaced with the composite material prepared in Material Example 5.

Compared with the method for preparing the photoelectric device in Device Example 1, a method for preparing the photoelectric device in this Example has a difference that step S10.6 is replaced with “with reference to the preparation method of the composite material in Material Example 5, the electron functional layer was formed on one side of the auxiliary layer away from the light-emitting layer”.

### Device Example 6

This embodiment provides a photoelectric device and a preparation method thereof. Compared with the photoelectric device in Device Example 1, the photoelectric device in this Example has a difference that the material of the hole transport layer is replaced with PF8Cz purchased from Dongguan Fuan Optoelectronics Technology Co., Ltd.

Compared with the method for preparing the photoelectric device in Device Example 1, a method for preparing the photoelectric device in this Example has a difference that “a TFB solution with a concentration of 8 mg/mL” in step S10.3 is replaced with “a PF8Cz solution with a concentration of 8 mg/mL”. A solvent of the PF8Cz solution was chlorobenzene.

### Device Example 7

This embodiment provides a photoelectric device and a preparation method thereof. Compared with the photoelectric device in Device Example 1, the photoelectric device in this Example has a difference that the photoelectric device does not include the auxiliary layer.

Compared with the method for preparing the photoelectric device in Device Example 1, a method for preparing the photoelectric device in this Example has differences that remove step S10.5, and step S10.6 is replaced with “with reference to the preparation method of the composite material in Material Example 1, the electron functional layer was formed on one side of the light-emitting layer away from the hole transport layer”.

### Device Example 8

This embodiment provides a photoelectric device and a preparation method thereof. Compared with the photoelectric device in Device Example 1, the photoelectric device in this Example has differences that the photoelectric device does not include the auxiliary layer, and the material of the hole transport layer is replaced with PF8Cz.

Compared with the method for preparing the photoelectric device in Device Example 1, a method for preparing the photoelectric device in this Example has differences that remove step S10.5, step S10.6 is replaced with “with reference to the preparation method of the composite material in Material Example 1, an electron functional layer was formed on one side of the light-emitting layer away from the hole transport layer”, and “a TFB solution with a concentration of 8 mg/mL” in step S10.3 is replaced with “a PF8Cz solution with a concentration of 8 mg/mL”. A solvent of the PF8Cz solution was chlorobenzene.

### Device Comparative Example 1

This comparative example provides a photoelectric device and a preparation method thereof. Compared with the photoelectric device in Device Example 1, the photoelectric device in this comparative example has differences that the material of the electron functional layer is replaced with Zn_{0.85}Mg_{0.15}O in Material Example 1, and the photoelectric device does not include the auxiliary layer.

Compared with the method for preparing the photoelectric device in Device Example 1, a method for preparing the photoelectric device in this comparative example has differences that remove step S10.5, and step S10.6 is replaced with “a Zn_{0.85}Mg_{0.15}O solution with a concentration of 30 mg/mL was spin-coated on one side of the light-emitting layer away from the hole transport layer under a nitrogen atmosphere with a normal temperature and a normal pressure, and then the electron functional layer was formed by heating at 100° C. under a nitrogen atmosphere for curing”.

### Device Comparative Example 2

This comparative example provides a photoelectric device and a preparation method thereof. Compared with the photoelectric device in Device Example 1, the photoelectric device in this comparative example has differences that the material of the electron functional layer is replaced with Zn_{0.85}Mg_{0.15}O in Material Example 1, the photoelectric device does not include the auxiliary layer, and the material of the hole transport layer is replaced with PF8Cz.

Compared with the method for preparing the photoelectric device in Device Example 1, a method for preparing the photoelectric device in this comparative example has differences that remove step S10.5, step S10.6 is replaced with “a Zn_{0.85}Mg_{0.15}O solution with a concentration of 30 mg/mL was spin-coated on one side of the light-emitting layer away from the hole transport layer under a nitrogen atmosphere with a normal temperature and a normal pressure, and then the electron functional layer was formed by heating at 100° C. under a nitrogen atmosphere for curing”, and “a TFB solution with a concentration of 8 mg/mL” in step S10.3 is replaced with “a PF8Cz solution with a concentration of 8 mg/mL”. A solvent of the PF8Cz solution was chlorobenzene.

### Device Comparative Example 3

This comparative example provides a photoelectric device and a preparation method thereof. Compared with the photoelectric device in Device Example 1, the photoelectric device in this comparative example has a difference that the material of the electron functional layer is replaced with Zn_{0.85}Mg_{0.15}O in Material Example 1.

Compared with the method for preparing the photoelectric device in Device Example 1, a method for preparing the photoelectric device in this comparative example has a difference that step S10.6 is replaced with “a Zn_{0.85}Mg_{0.15}O solution with a concentration of 30 mg/mL was spin-coated on one side of the light-emitting layer away from the hole transport layer under a nitrogen atmosphere with a normal temperature and a normal pressure, and then the electron functional layer was formed by heating at 100° C. under a nitrogen atmosphere for curing”.

### Device Comparative Example 4

This comparative example provides a photoelectric device and a preparation method thereof. Compared with the photoelectric device in Device Example 1, the photoelectric device in this comparative example has differences that the material of the electron functional layer is replaced with Zn_{0.85}Mg_{0.15}O in Material Example 1, and the material of the hole transport layer is replaced with PF8Cz.

Compared with the method for preparing the photoelectric device in Device Example 1, a method for preparing the photoelectric device in this comparative example has differences that step S10.6 is replaced with “a Zn_{0.85}Mg_{0.15}O solution with a concentration of 30 mg/mL was spin-coated on one side of the light-emitting layer away from the hole transport layer under a nitrogen atmosphere with a normal temperature and a normal pressure, and then the electron functional layer was formed by heating at 100° C. under a nitrogen atmosphere for curing”, and “a TFB solution with a concentration of 8 mg/mL” in step S10.3 is replaced with “a PF8Cz solution with a concentration of 8 mg/mL”. A solvent of the PF8Cz solution was chlorobenzene.

### Device Comparative Example 5

This comparative example provides a photoelectric device and a preparation method thereof. Compared with the photoelectric device in Device Example 1, the photoelectric device in this comparative example has a difference that the material of the electron functional layer is replaced with the composite material prepared in Material Comparative Example 1.

Compared with the method for preparing the photoelectric device in Device Example 1, a method for preparing the photoelectric device in this Example has a difference that step S10.6 is replaced with “with reference to the preparation method of the composite material in Material Comparative Example 1, the electron functional layer was formed on one side of the auxiliary layer away from the light-emitting layer”.

### Device Comparative Example 6

This comparative example provides a photoelectric device and a preparation method thereof. Compared with the photoelectric device in Device Example 1, the photoelectric device in this comparative example has a difference that the material of the electron functional layer is replaced with the composite material prepared in Material Comparative Example 2.

Compared with the method for preparing the photoelectric device in Device Example 1, a method for preparing the photoelectric device in this Example has a difference that step S10.6 is replaced with “with reference to the preparation method of the composite material in Material Comparative Example 2, the electron functional layer was formed on one side of the auxiliary layer away from the light-emitting layer”.

### Test Example

Performances of photoelectric devices after one hour of the encapsulation in Device Examples 1 to 8 and Device Comparative Examples 1 to 6 were tested by a Fostar FPD optical characteristic measuring equipment. The performance test was performed at a temperature of 25° C. and a relative humidity of 40%.

A turn-on voltage, currents, brightness, a luminescence spectrum and other parameters of each photoelectric device were obtained by a Fostar FPD optical characteristic measuring equipment, and then some key parameters such as a maximum external quantum efficiency (EQEₘₐₓ, %) and a power efficiency were calculated.

Test results of photoelectric devices are shown in Table 1 below:

TABLE 1

| | EQEₘₐₓ |
|---|---|
| items | (%) |
| Device Example 1 | 20.2 |
| Device Example 2 | 19.1 |
| Device Example 3 | 19.5 |
| Device Example 4 | 18.7 |
| Device Example 5 | 19.3 |
| Device Example 6 | 25.3 |
| Device Example 7 | 11.2 |
| Device Example 8 | 20.8 |
| Device Comparative Example 1 | 6.1 |
| Device Comparative Example 2 | 9.6 |
| Device Comparative Example 3 | 8.6 |
| Device Comparative Example 4 | 18.6 |
| Device Comparative Example 5 | 5.3 |
| Device Comparative Example 6 | 5.1 |

As can be seen from Table 1, compared with photoelectric devices in Device Comparative Examples 1 to 6, device efficiencies of photoelectric devices in Device Examples 1 to 8 are higher. Taking Device Examples 1 and Device Comparative Example 1 as examples, the device efficiency of the photoelectric device in Device Example 1 is 3.3 times that of the photoelectric device in Device Comparative Example 1.

The material of the electron functional layer includes the first metal oxide and the metal halide including magnesium element, where the first metal oxide is selected from one or more of ZnO and Zn₍₁₋ₓ₎MgₓO, in such a way that the electron injection level may be appropriately reduced, thereby promoting electron-hole transport balance, and thus improving the device efficiency of the photoelectric device.

Furthermore, adding an auxiliary layer made of an insulating compound between the electron functional layer and the light-emitting layer may further promote electron-hole transport balance.

In addition, compared with the material of the hole transport layer is TFB, the material of the hole transport layer is PF8Cz may further improve the device efficiency of the photoelectric device, because PF8Cz has stronger structural rigidity than TFB that might effectively suppress a problem of electron leakage in the photoelectric device.

The device efficiency of the photoelectric device in Device Comparative Example 5 or Device Comparative Example 6 are low, because a metal element selected from sodium or potassium in the metal halide improves the conductivity of the electron functional layer, thereby improving the electron injection level, further exacerbating the electron-hole transport imbalance, resulting in low device efficiency.

The composite material, the film, and the photoelectric device by embodiments of the present disclosure are described in detail above, and specific examples have been applied herein to illustrate principles and implement measures. The foregoing description of embodiments is provided merely to help understand a method and a core idea of the present disclosure. Those skilled in the art may change specific embodiments and scope of the present disclosure according to ideas of the present disclosure. In summary, contents of the specification should not be construed as limiting the present disclosure.

What is claimed is:

1. A composite material comprising a first metal oxide and a metal halide, wherein the metal halide comprises magnesium element.

2. The composite material according to claim 1, wherein the first metal oxide comprises one or more of ZnO and Zn₍₁₋ₓ₎MgₓO, where x is greater than 0 and not more than 0.5;
the first metal oxide is in the form of nanoparticles, and an average particle size of the first metal oxide ranges from 2 nm to 20 nm.

3. The composite material according to claim 2, wherein x is not less than 0.05 and not more than 0.2.

4. The composite material according to claim 2, wherein the first metal oxide is Zn₍₁₋ₓ₎MgₓO, and the metal halide is MgCl₂.

5. The composite material according to claim 1, wherein a mass ratio of the first metal oxide to the metal halide is 1:(0.01˜0.1).

6. A film comprising a first metal oxide and a metal halide, wherein the metal halide comprises magnesium element.

7. The film according to claim 6, wherein the first metal oxide comprises one or more of ZnO and Zn₍₁₋ₓ₎MgₓO, where x is greater than 0 and not more than 0.5;
the first metal oxide is in the form of nanoparticles, and an average particle size of the first metal oxide ranges from 2 nm to 20 nm.

8. The film according to claim 6, wherein in the film, a mass ratio of the first metal oxide to the metal halide is 1:(0.01˜0.1).

9. The film according to claim 6, wherein the first metal oxide is Zn₍₁₋ₓ₎MgₓO, and the metal halide is MgCl₂.

10. A photoelectric device comprising:
an anode;
a cathode; and
multiple functional layers disposed between the anode and the cathode, wherein at least one of the multiple functional layers comprises a metal halide and a first metal oxide comprising magnesium element.

11. The photoelectric device according to claim 10, wherein the multiple functional layers comprise an electron functional layer, and a material of the electron functional layer comprises the metal halide and the first metal oxide.

12. The photoelectric device according to claim 11, wherein the first metal oxide comprises one or more of ZnO and Zn₍₁₋ₓ₎MgₓO, where x is greater than 0 and not more than 0.5;
the first metal oxide is in the form of nanoparticles, and an average particle size of the first metal oxide ranges from 2 nm to 20 nm.

13. The photoelectric device according to claim 12, wherein the first metal oxide is Zn₍₁₋ₓ₎MgₓO, and the metal halide is MgCl₂.

14. The photoelectric device according to claim 13, wherein in the electron functional layer, a mass ratio of the first metal oxide to the metal halide is 1:(0.01˜0.1).

15. The photoelectric device according to claim 11, wherein the multiple functional layers further comprise a light-emitting layer disposed between the electron functional layer and the anode, and a material of the light-emitting layer comprises one or more of an organic light-emitting material and a quantum dot light-emitting material;
the quantum dot light-emitting material is selected from one or more of a quantum dot with a single component, a quantum dot with a core-shell structure, an inorganic perovskite quantum dot, an organic perovskite quantum dot, and an organic-inorganic hybrid perovskite quantum dot; the quantum dot with a core-shell structure comprises one or more shell layers;
a material of the quantum dot with a single component, a material of the core of the quantum dot with a core-shell structure, and a material of a shell layer of the quantum dot with a core-shell structure are each independently selected from one or more of a group II-VI compound, a group IV-VI compound, a group III-V compound, a group III-VI compound, and a group I-III-VI compound;
the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-VI compound is selected from one or more of In₂S₃, In₂Se₃, InGaS₃, and InGaSe₃; the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of AgInS, AgInS₂, CuInS, CuInS₂, AgGaS₂, CuGaS₂, CuGaO₂, AgGaO₂, AgAlO₂, AgInGaS₂, and CuInGaS₂;
the inorganic perovskite quantum dot has a general structural formula of AMX₃, wherein A is Cs⁺, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion selected from one or more of Cl⁻, Br⁻, and I⁻;
the organic perovskite quantum dot has a general structural formula of CMX₃, where C is a formamidyl, M is a divalent metal cation selected from Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion selected from Cl⁻, Br⁻, or I⁻;
the organic-inorganic hybrid perovskite quantum dot has a general structural formula of BMX₃, where B is an organic amine cation, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion selected from one or more of Cl⁻, Br⁻, or I⁻.

16. The photoelectric device according to claim 15, wherein the multiple functional layers further comprise an auxiliary layer disposed between the electron functional layer and the light-emitting layer; a material of the auxiliary layer comprises a polymer material.

17. The photoelectric device according to claim 16, wherein the polymer material is selected from one or more of polymethyl methacrylate, polyethylene glycol terephthalate, polyvinyl pyrrolidone, polyethylene oxide, and polyimide.

18. The photoelectric device according to claim 11, wherein the multiple functional layers further comprise a hole functional layer disposed between the electron functional layer and the anode.

19. The photoelectric device according to claim 18, wherein a material of the hole functional layer is selected from one or more of an organic compound, a first inorganic compound material and a second inorganic compound material;
wherein the organic compound is selected from one or more of poly(3,4-ethylenedioxythiophene)-poly(styrenesulfonate), copper(II) phthalocyanine, titanyl phthalocyanine, 2,3,5,6-tetrafluoro-7,7,8,8-tetracyanoquinodimethane, hexaazatriphenylenehexacabonitrile, polyaniline, polypyrrole, poly(3-hexylthiophene-2,5-diyl), poly(n-vinylcarbazole), 4,4′-Bis(N-carbazolyl)-1,1′-biphenyl, poly[N,N′-bis(4-butylphenyl)-N,N′-bis(phenyl)-benzi, 4,4′-cyclohexylidenebis[N,N-bis(4-methylphenyl)aniline], poly(9,9-dioctylfluorene-co-N-(4-butylphenyl)diphenylamine), poly[(9,9-dioctylfluorenyl-2,7-diyl)-alt-(4,4′-(N-(4-butylphenyl), 4,4′,4″-tris(N-3-methylphenyl-N-phenylamino)triphenylamine, 4,4′,4″-tris(carbazol-9-yl)-triphenylamine, 4,4′,4″-tris[2-naphthyl(phenyl)amino]triphenylamine, N,N′-bis-(1-naphthalenyl)-N,N′-bis-phenyl-(1,1′-biphenyl)-4,4′-diamine, N,N′-bis(3-methylphenyl)-N,N′-diphenyl-benzidine, N,N′-bis[4-(diphenylamino)phenyl]-N,N′-diphenylbenzidine, N2,N7-diphenyl-N2,N7-di-m-tolyl-9,9′-spirobi[fluorene]-2,7-diamine, N2,N7-di-1-naphthalenyl-N2,N7-diphenyl-9,9′-spirobi[9h-fluorene]-2,7-diamine, poly[bis(4-phenyl)(2,4,6-trimethylphenyl)amine], poly((9,9-dioctylfluorenyl-2,7-diyl)-alt-(9-(2-ethylhexyl)-carbazole-3,6-diyl)), and 2,2′,7,7′-Tetrakis[N,N-di(4-methoxyphenyl)amino]-9,9′-spirobifluorene; and
the first inorganic compound material is selected from one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide; and
the second inorganic compound material comprises one or more of doped-type second inorganic compounds; a host material of a doped-type second inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, or tungsten sulphide, and a doping element of the doped-type second inorganic compound is selected from one or more of nickel, molybdenum, tungsten, vanadium, chromium, copper and platinum group metal elements.

20. The photoelectric device according to claim 19, wherein the hole functional layer comprises a hole injection layer and a hole transport layer disposed in stack, and the hole injection layer is closer to the anode than the hole transport layer;
a material of the hole injection layer is poly(3,4-ethylenedioxythiophene)-poly(styrenesulfonate), and a material of the hole transport layer is poly[(9,9-dioctylfluorenyl-2,7-diyl)-alt-(4,4′-(N-(4-butylphenyl) or poly((9,9-dioctylfluorenyl-2,7-diyl)-alt-(9-(2-ethylhexyl)-carbazole-3,6-diyl)).
